(19) United States
(12) Patent Application Publication
(10) Pub. No.: US 2025/0248289 A1
(43) Pub. Date: Jul. 31, 2025

(54) DISPLAY DEVICE AND METHOD OF MANUFACTURING THE SAME

(71) Applicant: Samsung Display Co., Ltd., Yongin-si (KR)

(72) Inventors: Younggu Kim, Yongin-si (KR); Sujeong Kim, Yongin-si (KR); Seungbeom Park, Yongin-si (KR); Bongsung Seo, Yongin-si (KR); Yun Jang, Yongin-si (KR); Baekkyun Jeon, Yongin-si (KR)

(73) Assignee: Samsung Display Co., Ltd., Yongin-si (KR)

(21) Appl. No.: 19/027,687

(22) Filed: Jan. 17, 2025

(30) Foreign Application Priority Data
Jan. 30, 2024 (KR) 10-2024-0014315

(51) Int. Cl. H10K 59/80; G09G 3/3233; H10K 59/12

(52) U.S. Cl. CPC H10K 59/8791; H10K 59/1201; G09G 3/3233; G09G 2300/0819; G09G 2300/0842; G09G 2300/0861

(57) ABSTRACT

A display device including a substrate, a light-emitting element disposed on the substrate and including a subpixel electrode, an emission layer, and an opposite electrode, a capping layer disposed on the light-emitting element, and a meta-layer disposed on the capping layer and including a patterned metal layer and a metal oxide layer disposed on the metal layer.

### CROSS-REFERENCE TO RELATED APPLICATION(S)

This application claims priority to and the benefits of Korean Patent Application No. 10-2024-0014315 under 35 U.S.C. § 119, filed on Jan. 30, 2024, in the Korean Intellectual Property Office, the contents of which are hereby incorporated by reference in its entirety.

### BACKGROUND

### 1. Technical Field

One or more embodiments relate to a display device and a method of manufacturing the same.

### 2. Description of the Related Art

A display device is an apparatus that visually displays data. The display device may be used as a display portion for small-sized products such as mobile phones or as a display portion for large-sized products such as televisions.

The display device may include a liquid crystal display device that does not emit light by itself but uses light from a backlight or a light-emitting display device including a display element capable of emitting light, and the display element may include an emission layer.

### SUMMARY

One or more embodiments include a display device with improved reliability and efficiency and a method of manufacturing the same. However, these objectives are illustrative and do not limit the scope of the disclosure.

Additional aspects will be set forth in part in the description which follows and, in part, will be apparent from the description, or may be learned by practice of the embodiments of the disclosure.

According to one or more embodiments, a display device may include a substrate, a light-emitting element disposed on the substrate and including a subpixel electrode, an emission layer, and an opposite electrode, a capping layer disposed on the light-emitting element, and a meta-layer disposed on the capping layer and including a patterned metal layer and a metal oxide layer disposed on the metal layer.

According to the embodiment, when viewed in a direction perpendicular to the substrate, the metal layer may be patterned into a shape of a rectangles.

According to the embodiment, the metal layer may include aluminum (Al), and the metal oxide layer may include aluminum oxide (Al₂O₃).

According to the embodiment, the metal layer may include at least one selected from silver (Ag), gold (Au), molybdenum (Mo), or vanadium (V), and the metal oxide layer may include at least one selected from silver oxide (Ag₂O), gold oxide (Au₂O₃), molybdenum oxide (MoOₓ), or vanadium oxide (V₂O₅).

According to the embodiment, the meta-layer may have a thickness of about 5 nm to about 10 nm.

According to the embodiment, the metal layer may include silicon (Si), and the metal oxide layer may include silicon dioxide (SiO₂).

According to the embodiment, interfacial adhesion between the metal layer and the metal oxide layer may be 5B as a result of a cross-cut test.

According to the embodiment, the metal oxide layer may have a flat upper surface.

According to one or more embodiments, a method of manufacturing a display device may include disposing a light-emitting element including a pixel electrode, an emission layer, and an opposite electrode on a substrate, disposing a capping layer on the light-emitting element, and forming, on the capping layer, a meta-layer including a patterned metal layer and a metal oxide layer.

According to the embodiment, when viewed in a direction perpendicular to the substrate, the metal layer may be patterned into a shape of a rectangles.

According to the embodiment, the forming of the meta-layer may include disposing a meta-layer-forming material on the capping layer, disposing a photoresist on at least a portion of the meta-layer-forming material, and oxidizing at least a portion of the meta-layer-forming material to form the patterned metal layer and the metal oxide layer.

According to the embodiment, the meta-layer-forming material on which the photoresist is not disposed may be oxidized to form the metal oxide layer.

According to the embodiment, only a portion adjacent to the photoresist, of the meta-layer-forming material on which the photoresist is disposed, may be oxidized to form the metal oxide layer.

According to the embodiment, a degree to which the meta-layer-forming material on which the photoresist is disposed is oxidized may be less than a degree to which the meta-layer-forming material on which the photoresist is not disposed is oxidized.

According to the embodiment, a thickness of the metal oxide layer disposed below the photoresist may be less than a thickness of the metal oxide layer on which the photoresist is not disposed.

According to the embodiment, the meta-layer-forming material and the metal layer may include at least one selected from aluminum (Al), silver (Ag), gold (Au), molybdenum (Mo), or vanadium (V).

According to the embodiment, the metal oxide layer may include at least one selected from aluminum oxide (Al₂O₃), silver oxide (Ag₂O), gold oxide (Au₂O₃), molybdenum oxide (MoOₓ), or vanadium oxide (V₂O₅).

According to the embodiment, interfacial adhesion between the metal layer and the metal oxide layer may be 5B as a result of a cross-cut test.

According to the embodiment, the thickness of the meta-layer-forming material may be about 5 nm or more and about 10 nm or less.

According to the embodiment, the metal layer may include silicon (Si), and the metal oxide layer may include silicon oxide (SiO₂).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic diagram of an equivalent circuit illustrating a subpixel circuit electrically connected to another subpixel, according to an embodiment;

FIG. 3 is a schematic cross-sectional view of a display panel according to an embodiment;

FIG. 4 is a schematic plan view of a metal layer of a meta-layer; and

FIGS. 5A, 5B, 6, 7, 8, and 9 are schematic cross-sectional views illustrating a method of manufacturing a display device.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that when an element such as a layer, film, region, or substrate is referred to as being “on” or “over” another element, it can be directly on the other element or intervening element(s) may also be present. In contrast, when an element is referred to as being “directly on” another element, no intervening elements are present.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

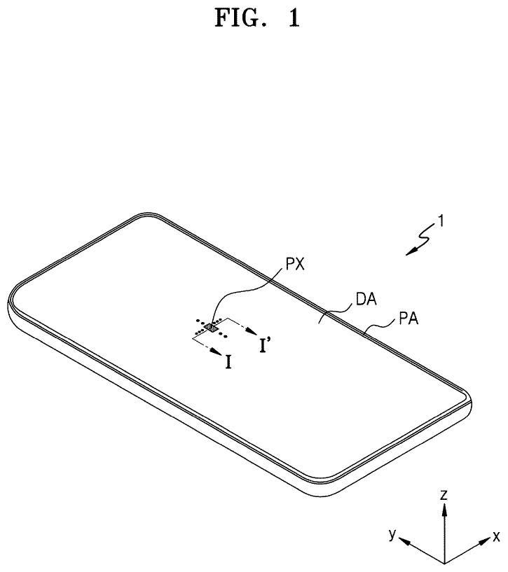

FIG. 1 schematically illustrates a perspective view of a display device according to an embodiment.

A display device according to embodiments may include devices that display moving images or still images and may be used as a display screen for mobile phones, smart phones, tablet personal computers (PCs), mobile communication terminals, electronic notebooks, e-books, portable multimedia players (PMPs), navigation, Ultra Mobile PCs (UMPCs), and also for various products such as televisions, laptop computers, monitors, billboards, and the Internet of Things (IoT). The display device according to an embodiment may be used in a wearable device such as a smartwatch, a watch phone, a glasses-type display, and a head mounted display (HMD). Furthermore, the display device according an embodiment may be used as a center information display (CID) arranged on an instrument panel of a vehicle, a center fascia, or a dashboard of a vehicle, a room mirror display functioning in place of a side mirror of a vehicle, and a display arranged on the back of a front seat as an entertaining element for a rear seat of a vehicle.

Referring to FIG. 1, a display device 1 may have an edge in a first direction and an edge in a second direction. Here, the first direction and the second direction may be directions that intersect with each other. For example, the first direction and the second direction may be at acute angles to each other. As another example, the first direction and the second direction may form an obtuse angle to each other or may be orthogonal to each other. Hereinafter, description will focus on a case where the first direction and the second direction are orthogonal to each other. For example, the first direction may be a x-direction or a −x-direction, and the second direction may be a y-direction or a −y-direction. A third direction perpendicular to the first direction and the second direction may be a z-direction or a −z-direction.

The display device 1 may include a display area DA and a peripheral area PA outside the display area DA. The display device 1 may provide a certain image by using light emitted from subpixels PX arranged in the display area DA. The peripheral area PA may be an area arranged outside the display area DA and may be a type of non-display area in which subpixels are not arranged. The display area DA may be completely surrounded by the peripheral area PA.

Hereinafter, an organic light-emitting display device is described as an example of a display according to an embodiment, but the display device of the disclosure is not limited thereto. As another example, the display device of the disclosure may be an inorganic light-emitting display (or an inorganic electroluminescent (EL) display device) or a quantum dot light-emitting display device. For example, an emission layer of a display element included in a display device include an organic material or an inorganic material. The display device may include an emission layer and quantum dots located on a path of light emitted from the emission layer.

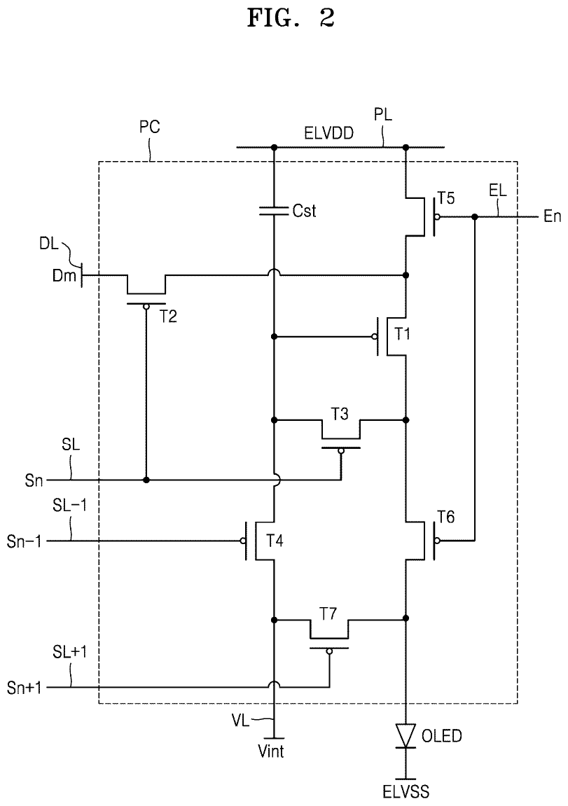

FIG. 2 is an equivalent circuit diagram schematically illustrating a subpixel circuit electrically connected to a subpixel, according to an embodiment.

Referring to FIG. 2, the subpixel may emit light through an organic light-emitting diode, and the organic light-emitting diode may be electrically connected to a subpixel circuit.

A subpixel circuit PC may include a first transistor T1, a second transistor T2, a third transistor T3, a fourth transistor T4, a fifth transistor T5, a sixth transistor T6, a seventh transistor T7, and a storage capacitor Cst.

The first transistor T1 may be a driving thin-film transistor connected to a driving voltage line PL and the storage capacitor Cst and may control, in response to a voltage value stored in the storage capacitor Cst, a driving current flowing from the driving voltage line PL and through an organic light-emitting diode OLED. The organic light-emitting diode OLED may emit light having a certain luminance according to a driving current. A second electrode (e.g., cathode) of the organic light-emitting diode OLED may receive a second power voltage ELVSS.

The second transistor T2 may be a switching thin-film transistor connected to a signal line SL and a data line DL and may be transmit a data voltage (or data signal, Dm) input from the data line DL to the first transistor T1, based on a scan signal (or a scan voltage, switching voltage, switching signal, Sn) input from the signal line SL.

The storage capacitor Cst may be connected to the driving voltage line PL and the first transistor T1. One electrode of the storage capacitor Cst may be connected to the driving voltage line PL, and the other electrode of the storage capacitor Cst may be connected to a gate of the first transistor T1. The storage capacitor Cst may store a difference between a first driving voltage ELVDD applied to the driving voltage line PL and a gate voltage of the first transistor T1, and may maintain the gate voltage of the first transistor T1.

The third transistor T3 may be a compensation thin-film transistor, and a gate electrode of the third transistor T3 may be connected to the signal line SL. A source (or drain) of the third transistor T3 may be connected to a drain (or source) of the first transistor T1 and may be connected to a first electrode (e.g., anode) of the organic light-emitting diode OLED via the sixth transistor T6. A drain (or source) of the third transistor T3 may be connected to the other electrode of the storage capacitor Cst, a source (or drain) of the fourth transistor T4, and the gate of the first transistor T1. The third transistor T3 may be turned on according to the scan signal Sn received through the signal line SL and may connect the gate and drain of the first transistor T1 to each other to diode-connect the first transistor T1.

The fourth transistor T4 may be an initialization thin-film transistor, and a gate of the fourth transistor T4 may be connected to a previous signal line SL−1. The drain (or source) of the fourth transistor T4 may be connected to an initialization voltage line VL. The source (or drain) of the fourth transistor T4 may be connected to the other electrode of the storage capacitor Cst, the drain (or source) of the third transistor T3, and the gate of the first transistor T1. The fourth transistor T4 may be turned on according to a previous scan signal Sn−1 received through the previous signal line SL−1 and perform an initialization operation of initializing a voltage of the gate of the first transistor T1 by transferring the initialization voltage Vint to the gate of the first transistor T1.

The fifth transistor T5 may be an operation control thin-film transistor, and a gate of the fifth transistor T5 may be connected to an emission control line EL. A source (or drain) of the fifth transistor T5 may be connected to the driving voltage line PL. The drain (or source) of the fifth transistor T5 may be connected to the source (or drain) of the first transistor T1 and a drain (or source) of the second transistor T2.

The sixth transistor T6 may be an emission control thin-film transistor, and a gate electrode thereof may be connected to the emission control line EL. A source (or drain) of the sixth transistor T6 may be connected to the drain (or source) of the first transistor T1 and the source (or drain) of the third transistor T3. The drain (or source) of the sixth transistor T6 may be electrically connected to the first electrode of the organic light-emitting diode OLED. The fifth transistor T5 and the sixth transistor T6 may be simultaneously turned on according to an emission control signal En received through the emission control line EL to transmit the driving voltage ELVDD to the organic light-emitting diode OLED and a driving current flows to the organic light-emitting diode OLED.

The seventh transistor T7 may be an initialization thin-film transistor that initializes the first electrode of the organic light-emitting diode OLED. A gate of the seventh transistor T7 may be connected to a next signal line SL+1. A source (or drain) of the seventh transistor T7 may be connected to the first electrode of the organic light-emitting diode OLED. The drain (or source) of the seventh transistor T7 may be connected to the initialization voltage line VL. The seventh transistor T7 may be turned on according to a next scan signal Sn+1 received through the next signal line SL+1 to initialize the first electrode of the organic light-emitting diode OLED.

In FIG. 2, the fourth transistor T4 and the seventh transistor T7 respectively connected to the previous signal line SL−1 and the next signal line SL+1 are illustrated. However, both the fourth transistor T4 and the seventh transistor T7 may be connected to the previous signal line SL−1 and driven according to the previous scan signal Sn−1.

One electrode of the storage capacitor Cst may be connected to the driving voltage line PL. The other electrode of the storage capacitor Cst may be connected together to the gate of the first transistor T1, the drain (or source) of the third transistor T3, and the source (or drain) of the fourth transistor T4.

The second electrode of the organic light-emitting diode OLED may receive a common voltage ELVSS. The organic light-emitting diode OLED may emit light by receiving a driving current from the first transistor T1.

In an embodiment, the transistors T1 to T7 may all include a semiconductor layer including silicon. However, the disclosure is not limited thereto.

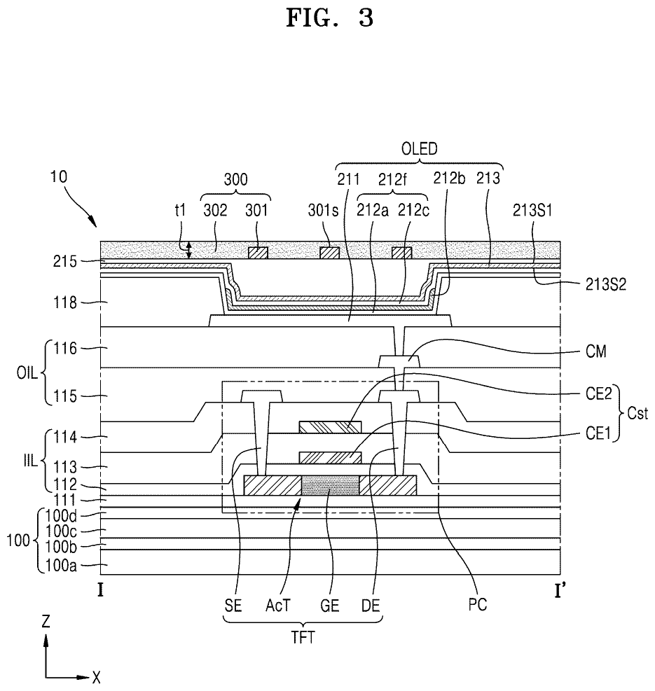

In an embodiment, at least one transistor among the transistors T1 to T7 may include a semiconductor layer including oxide, and the remaining transistors may include a semiconductor layer including silicon. The first transistor T1, which directly affects the brightness of a display panel 10 of FIG. 3, may be a silicon semiconductor including polycrystalline silicon which has high reliability, and the display panel 10 with a high resolution may be implemented, accordingly.

An oxide semiconductor has high carrier mobility and low leakage current, and thus, the voltage drop thereof is not large even if the driving time is long. For example, even during low-frequency driving, the color change of an image due to the voltage drop is not significant, and thus low-frequency driving is possible. As described above, since an oxide semiconductor has the advantage of low leakage current, an oxide semiconductor may be used in at least one of the third transistor T3 and the fourth transistor T4 connected to the gate of the first transistor T1 to prevent leakage current that may flow to the gate of the transistor T1 and reduce power consumption. A signal line and/or a voltage line may be added to the subpixel circuit PC of FIG. 2. Transistors other than the third transistor T3 and the fourth transistor T4 may include a semiconductor layer including oxide. For example, the seventh transistor T7 may include a semiconductor layer including an oxide.

FIG. 2 illustrates that an equivalent circuit diagram of one subpixel includes seven transistors and one capacitor, but the disclosure is not limited thereto. The number of transistors and capacitors may be different from that illustrated in FIG. 2.

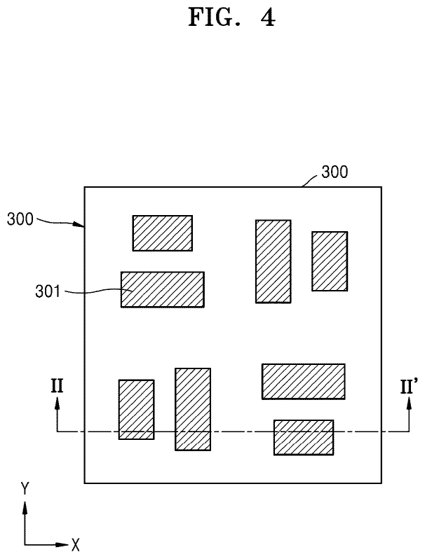

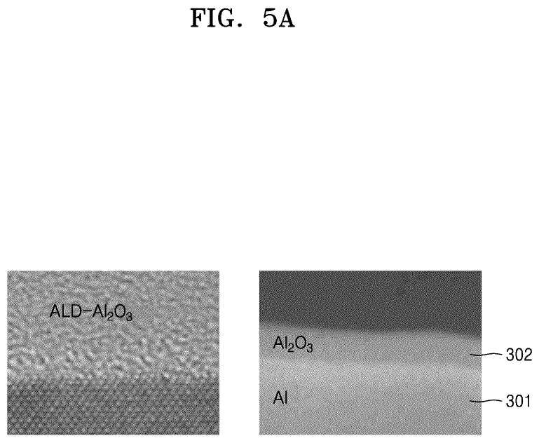

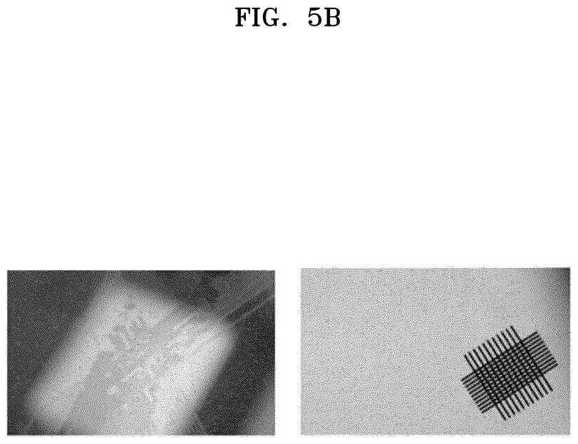

FIG. 3 schematically illustrates a cross-sectional view of a display panel according to an embodiment. In detail, FIG. 3 schematically illustrates a cross-sectional view of a display area of a display device according to an embodiment. FIG. 4 schematically illustrates a plan view of a metal layer of a meta-layer. FIG. 5A is a photographic image schematically showing a cross-sectional view of a metal layer and a metal oxide layer, and FIG. 5B is a photographic image schematically showing a result of testing the interfacial adhesion between the metal and metal oxide layer by cross-cut.

Referring to FIG. 3, the display panel 10 may include a substrate 100, an inorganic insulating layer IIL, an organic insulating layer OIL, a subpixel circuit PC, a connection electrode CM, an organic light-emitting diode OLED, a pixel-defining layer 118, and a meta-layer 300. For example, in the display area DA of the display panel 10, the substrate 100, the inorganic insulating layer IIL, the organic insulating layer OIL, the subpixel circuit PC, the connection electrode CM, the organic light-emitting diode OLED, and the pixel-defining layer 118 may be arranged.

The substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the substrate 100.

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

The first barrier layer 100b and the second barrier layer 100d may include barrier layers that prevent penetration of external foreign substances and may be a single layer or a multi-layer including an inorganic material such as silicon nitride (SiNₓ), silicon oxide (SiO₂), and/or silicon oxynitride (SiON).

A buffer layer 111 may be disposed on the substrate 100. The buffer layer 111 may include an inorganic insulating material such as silicon nitride (SiNₓ), silicon oxynitride (SiON), and silicon oxide (SiO₂) and may be a single layer or multi-layer including the inorganic insulating material described above.

The inorganic insulating layer IIL may be disposed on the buffer layer 111. The inorganic insulating layer IIL may include a first inorganic insulating layer 112, a second inorganic insulating layer 113, and a third inorganic insulating layer 114.

A subpixel circuit PC may be disposed in the display area DA. The subpixel circuit PC may include a thin-film transistor TFT and a storage capacitor Cst. The thin-film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. In another example, the semiconductor layer Act may include amorphous silicon, an oxide semiconductor, an organic semiconductor, etc. The semiconductor layer Act may include a channel region, and a drain region and a source region respectively disposed in both sides of the channel region.

The gate electrode GE may be disposed on the semiconductor layer Act. The gate electrode GE may overlap the channel region. The gate electrode GE may include a low-resistance metal material. The gate electrode GE may include a conductive material including molybdenum (Mo), aluminum (Al), copper (Cu), titanium (Ti), etc. and may be formed as a multi-layer or single layer including the materials described above.

The first inorganic insulating layer 112 may be arranged between the semiconductor layer Act and the gate electrode GE. The first inorganic insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second inorganic insulating layer 113 may be disposed above the gate electrode GE. The second inorganic insulating layer 113 may cover the gate electrode GE. The second inorganic insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be disposed on the second inorganic insulating layer 113. The upper electrode CE2 may overlap the gate electrode GE disposed thereunder. The gate electrode GE and the upper electrode CE2 overlapping with the second inorganic insulating layer 113 therebetween may form the storage capacitor Cst. The gate electrode GE may function as a lower electrode CE1 of the storage capacitor Cst.

As described above, the storage capacitor Cst and the thin-film transistor TFT may overlap each other. However, the disclosure is not limited thereto. For example, the storage capacitor Cst is formed so as not to overlap the thin-film transistor TFT. The lower electrode CE1 of the storage capacitor Cst may be a separate component from the gate electrode GE of the thin-film transistor TFT and may be provided apart from the gate electrode GE of the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single-layer or multi-layer including the materials described above.

The third inorganic insulating layer 114 may be disposed on the upper electrode CE2. The third inorganic insulating layer 114 may cover the upper electrode CE2. The third inorganic insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third inorganic insulating layer 114 may be a single layer or a multi-layer including the inorganic insulating materials described above.

The drain electrode DE and the source electrode SE may each be located on the third inorganic insulating layer 114. The drain electrode DE and the source electrode SE may be each connected to the semiconductor layer Act through contact holes provided in the first inorganic insulating layer 112, the second inorganic insulating layer 113, and the third inorganic insulating layer 114. The drain electrode DE and the source electrode SE may include a material with good conductivity. The drain electrode DE and the source electrode SE may include a conductive material including molybdenum (Mo), aluminum (Al), copper (Cu), titanium (Ti), etc. and may be a multi-layer or a single layer including the materials described above. For example, the drain electrode DE and the source electrode SE may have a multi-layer structure of Ti/Al/Ti.

The organic insulating layer OIL may be disposed on the inorganic insulating layer IIL. The organic insulating layer OIL may include a first organic insulating layer 115 and a second organic insulating layer 116. In FIG. 3, two organic insulating layers OIL are illustrated, but the disclosure is not limited thereto. There may be three or four organic insulating layers OIL.

The first organic insulating layer 115 may cover the drain electrode DE and the source electrode SE. The first organic insulating layer 115 may include general-purpose polymers such as polymethylmethacrylate (PMMA) or polystyrene (PS), polymer derivatives having a phenolic group, acrylic polymers, imide polymers, aryl ether polymers, amide polymers, fluorine polymers, p-xylene-based polymers, vinyl alcohol-based polymers, and blends thereof.

The connection electrode CM may be disposed on the first organic insulating layer 115. The connection electrode CM may be connected to the drain electrode DE or the source electrode SE through a contact hole in the first organic insulating layer 115. The connection electrode CM may include a material with good conductivity. The connection electrode CM may include a conductive material including molybdenum (Mo), aluminum (Al), copper (Cu), titanium (Ti), etc. and may be formed as a multi-layer or single layer including the materials described above. For example, the connection electrode CM may have a multi-layer structure of Ti/Al/Ti.

A second organic insulating layer 116 may be disposed on the connection electrode CM. The second organic insulating layer 116 may cover the connection electrode CM. The second organic insulating layer 116 may include the same material as the first organic insulating layer 115 or may include a different material.

A light-emitting diode may be disposed on the second organic insulating layer 116. For example, an organic light-emitting diode OLED may be disposed on the second organic insulating layer 116. In another example, although not shown, an inorganic light-emitting diode or the like may be disposed on the second organic insulating layer 116.

The organic light-emitting diode OLED may emit red, green, or blue light, or emit red, green, blue, or white light. The organic light-emitting diode OLED may include a subpixel electrode 211, an emission layer 212b, a functional layer 212f, an opposite electrode 213, and a capping layer 215.

The subpixel electrode 211 may be disposed on the second organic insulating layer 116. The subpixel electrode 211 may be electrically connected to the connection electrode CM through a contact hole defined in the second organic insulating layer 116. The subpixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the subpixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the subpixel electrode 211 may further include a film including ITO, IZO, ZnO, or In₂O₃ above or below the above-described reflective layer. For example, the subpixel electrode 211 may have a multi-layer structure of ITO/Ag/ITO.

The pixel-defining layer 118 may be disposed on the subpixel electrode 211, with an opening defined to expose at least a portion of the subpixel electrode 211. An emission area of light emitted from the organic light-emitting diode OLED may be defined by an opening defined in the pixel-defining layer 118. For example, a width of the opening may correspond to a width of the emission area.

The pixel-defining layer 118 may include an organic insulating material. For example, the pixel-defining layer 118 may include an inorganic insulating material such as silicon nitride, silicon oxynitride, or silicon oxide. In another example, the pixel-defining layer 118 may include an organic insulating material and an inorganic insulating material. In an embodiment, the pixel-defining layer 118 may include a light blocking material. The light blocking material may include carbon black, carbon nanotubes, a resin or paste including black dye, metal particles such as nickel, aluminum, molybdenum, and alloys thereof, metal oxide particles (e.g., chromium oxide) or metal nitride particles (e.g., chromium nitride), etc. In case that the pixel-defining layer 118 includes a light blocking material, reflection of external light by metal structures disposed below the pixel-defining layer 118 may be reduced.

The emission layer 212b may be disposed in the opening of the pixel-defining layer 118. The emission layer 212b may include a polymer or low-molecular organic material that emits light of a certain color.

The functional layer 212f may include a first functional layer 212a and a second functional layer 212c. The first functional layer 212a may be arranged between the subpixel electrode 211 and the emission layer 212b, and the second functional layer 212c may be arranged between the emission layer 212b and the opposite electrode 213. However, at least one of the first functional layer 212a or the second functional layer 212c may be omitted. Hereinafter, a detailed description will be given focusing on a case where the first functional layer 212a and the second functional layer 212c are respectively disposed.

The first functional layer 212a may include a hole transport layer HTL and/or a hole injection layer HIL. The second functional layer 212c may include an electron transport layer ETL and/or an electron injection layer EIL. The first functional layer 212a and/or the second functional layer 212c may be a common layer formed to completely cover the substrate 100, like the opposite electrode 213, which will be described later.

The opposite electrode 213 may be disposed on the functional layer 212f. The opposite electrode 213 may include a conductive material with a low work function. For example, the opposite electrode 213 may include a transparent or semi-transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another example, the opposite electrode 213 may further include a layer such as oxide (ITO), indium zinc oxide (IZO), zinc oxide (ZnO), indium oxide (In₂O₃), on the transparent or semi-transparent layer including the above-described material.

In an embodiment, the capping layer 215 may be disposed on the opposite electrode 213. The capping layer 215 may include LiF, an inorganic material, or/and an organic material.

In an embodiment, referring to FIGS. 3 and 4, the meta-layer 300 may be disposed on the capping layer 215. The meta-layer 300 may include a metal layer 301 and a metal oxide layer 302. The metal oxide layer 302 may be disposed on the metal layer 301.

In case that light emitted from the organic light-emitting diode OLED may incident on an interface 213s1 between the opposite electrode 213 and the capping layer 215 (e.g., dielectric) or an interface 213s2 between the opposite electrode 213 and the second functional layer 212c (e.g., dielectric), photons of the light are combined with free electrons of the opposite electrode 213, which may generate surface plasmon polariton (SPP). SPP is an electromagnetic wave that moves along the interface between a metal and a dielectric and may include both the charge movement of a metal included in the opposite electrode 213 and the electromagnetic wave of the dielectric. As a result, light loss may occur in which light emitted from the organic light-emitting diode OLED cannot be emitted to the outside.

In an embodiment, the meta-layer 300 including the metal layer 301 and the metal oxide layer 302 disposed on the metal layer 301 may be disposed on the capping layer 215. The meta-layer 300 may be arranged to contact an upper surface of the capping layer 215 and thus adjacent to the interface 213s1 between the opposite electrode 213 and the capping layer 215 or the interface 213s2 between the opposite electrode 213 and the second functional layer 212c where SPPs are generated. In case that light emitted from the organic light-emitting diode OLED is incident on an interface 301s between the metal layer 301 and the metal oxide layer 302 (e.g., a dielectric) of the meta-layer 300, photons of light and free electrons of the metal layer 301 are combined with each other, thereby causing localized surface plasmon (LSP), in which the free electrons of the metal layer 301 oscillate collectively on a local surface. Due to the LSP on the interface 301s between the metal layer 301 and the metal oxide layer 302, an electromagnetic field may be generated on the interface 301s between the metal layer 301 and the metal oxide layer 302.

Photons trapped in the interface 213s1 between the opposite electrode 213 and the capping layer 215 or the interface 213s2 between the opposite electrode 213 and the second functional layer 212c may be released to the outside due to the electromagnetic field generated adjacent to the photons at an interface 301s between the metal layer 301 and the metal oxide layer 302 of the meta-layer 300 disposed on the capping layer 215, thereby improving light extraction efficiency. For example, the electromagnetic field at the interface 213s1 between the opposite electrode 213 and the capping layer 215 or the electromagnetic field at the interface 213s2 between the opposite electrode 213 and the second functional layer 212c may interact with an electromagnetic field adjacent thereto at the interface 301s on the metal layer 301 and the metal oxide layer 302 of the meta-layer 300 disposed on the capping layer 215, so that photons trapped in the interfaces 213s1 and 213s2 may be released to the outside, improving light extraction efficiency.

The metal layer 301 of the meta-layer 300 may be a patterned metal layer 301. As illustrated in FIG. 4, the metal layer 301 of the meta-layer 300 may be provided in a rectangular shape when viewed in a direction perpendicular to the substrate 100. Due to the design characteristics that the metal layer 301 of the meta-layer 300 is patterned in a rectangular shape, reflectance of light incident on a display device from the outside may be reduced. In other embodiments, the material of the metal layer 301 of the meta-layer 300 may absorb external light in a certain wavelength range and reduce the reflectance of light incident on the display device.

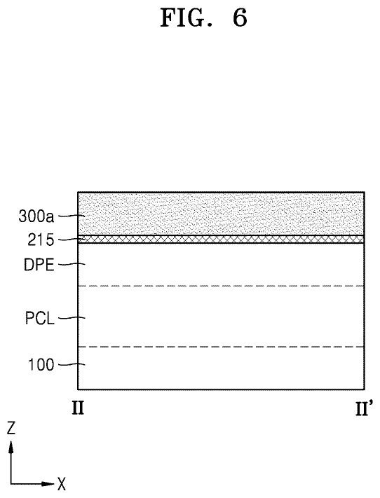

The metal layer 301 of the meta-layer 300 may include aluminum (Al). Since the metal layer 301 and the metal oxide layer 302 of the meta-layer 300 are formed using a meta-layer-forming material (300a, see FIG. 6), In case that the metal layer 301 of the meta-layer 300 includes aluminum (Al), the metal oxide layer 302 may include aluminum oxide (Al₂O₃). Aluminum (Al) may form plasmons in the entire range of visible light, and thus, the metal layer 301 may include aluminum (Al) in order to efficiently form the LSP at the interface 301s between the metal layer 301 and the metal oxide layer 302. However, the disclosure is not limited thereto. In another embodiment, the metal layer 301 of the meta-layer 300 may include silicon (Si). The metal oxide layer 302 may include silicon dioxide (SiO₂). The metal layer 301 and the metal oxide layer 302 of the meta-layer 300 may each include silver (Ag) and silver oxide (Ag₂O), gold (Au) and gold oxide (Au₂O₃), molybdenum (Mo) and molybdenum oxide (MoO₂), or vanadium (V) and vanadium oxide (V₂O₅).

After disposing the meta-layer-forming material (300a, see FIG. 6) on the substrate 100, at least a portion of the meta-layer-forming material (300a, see FIG. 6) may be oxidized to form the metal oxide layer 302, and an unoxidized meta-layer-forming material (300a, see FIG. 6) may form the patterned metal layer 301. Rather than simply forming the metal oxide layer 302 on the metal layer 301, the metal oxide layer 302 and the metal layer 301 may be formed through a chemical reaction that oxidizes at least a portion of the meta-layer-forming material 300a, and thus, the metal layer 301 and the metal oxide layer 302 may be chemically bonded to each other. In case of forming the metal oxide layer 302 and the metal layer 301 by oxidizing at least a portion of the meta-layer-forming material 300a, the interfacial adhesion between the metal layer 301 and the metal oxide layer 302 may be improved compared to in case that the metal oxide layer 302 is physically disposed on the metal layer 301.

Referring to FIG. 5A, a photographic image on the left shows a cross-section in case that a metal oxide layer is physically disposed on a metal layer, and a photographic image on the right shows a cross-section in case of forming the metal oxide layer 302 and the metal layer 301 by oxidizing at least a portion of the meta-layer-forming material 300a. In case of forming the metal oxide layer 302 and the metal layer 301 by oxidizing at least a portion of the meta-layer-forming material 300a (photographic image on the right), compared to in case that the metal oxide layer is physically disposed on the metal layer (photographic image on the left), the boundary between the metal layer 301 and the metal oxide layer 302 is ambiguous.

Referring to FIG. 5B, the interfacial adhesion between the metal layer 301 and the metal oxide layer 302 may be measured using a cross-cut test. The photographic image on the left shows a result of a cross-cut test in case of physically disposing a metal oxide layer on a metal layer, and the photographic image on the right shows a result of a cross-cut test in case of forming the metal oxide layer 302 and the metal layer 301 by oxidizing at least a portion of the meta-layer-forming material 300a. The cross-cut test is a method to quantitatively check the size of adhesion according to the proportion of the remaining thin film in case that the surface of the thin film is scratched with a fork-shaped knife and torn off with a standardized tape. If adhesion is excellent, 100% of the thin film may remain (5B), and if adhesion is relatively low, the remaining percentage of the thin film due to peeling may be less than 35% (0B). Referring to the photographic image on the left, in case that a metal oxide layer is physically disposed on a metal layer, it is found that the proportion of the remaining metal oxide layer is less than 35% (0B) as a result of a cross-cut test. On the other hand, referring to the photographic image on the right, in case that at least a portion of the meta-layer-forming material 300a is oxidized to form the metal oxide layer 302 and the metal layer 301, a result of a cross-cut test showed that the proportion of the remaining metal oxide layer 302 is 100% (5B).

In addition, since the metal oxide layer 302 and the metal layer 301 are formed by a chemical reaction that oxidizes at least a portion of the meta-layer-forming material 300a, an upper surface of the metal oxide layer 302 on the metal layer 301 may be flat.

A thickness t1 (see FIG. 3) of the meta-layer 300, a layer including the metal layer 301 and the metal oxide layer 302, may be about 5 nm to about 10 nm. In case that the thickness t1 of the meta-layer 300 is less than about 5 nm, the thickness may not be sufficient to generate the LSP at the interface 301s between the metal layer 301 and the metal oxide layer 302. If the thickness of the meta-layer 300 exceeds about 10 nm, light emitted from the organic light-emitting diode OLED may not be transmitted to the outside and light extraction efficiency may decrease.

Although not shown, an encapsulation layer may be disposed on the organic light-emitting diode OLED. In detail, the encapsulation layer may be disposed on the opposite electrode 213 and/or the capping layer 215. In an embodiment, the encapsulation layer may include at least one inorganic layer and at least one organic layer. The encapsulation layer may include a first inorganic encapsulation layer, an organic encapsulation layer, and a second inorganic encapsulation layer that are sequentially stacked.

The first inorganic encapsulation layer and the second inorganic encapsulation layer may include at least one inorganic material selected from the group consisting of aluminum oxide, titanium oxide, tantalum oxide, hafnium oxide, zinc oxide, silicon oxide, silicon nitride, and silicon oxynitride. The first inorganic encapsulation layer and the second inorganic encapsulation layer may be a single layer or a multi-layer including the above-described materials. The organic encapsulation layer may include a polymer-based material. The polymer-based material may include an acrylic resin, an epoxy-based resin, polyimide, polyethylene, and the like. In an embodiment, the organic encapsulation layer may include acrylate.

Although not shown, a touch sensor layer including touch insulating layers and conductive layers may be disposed on the encapsulation layer.

The display device illustrated in FIG. 3 is a top-emitting display device, and the meta-layer 300 disposed on the organic light-emitting diode OLED is illustrated, but the disclosure is not limited thereto. In another embodiment, the meta-layer 300 and a manufacturing process thereof according to an embodiment may be applied to a bottom-emitting display device, and the meta-layer 300 according to an embodiment may be disposed below the organic light-emitting diode OLED.

FIGS. 6 to 9 are cross-sectional views schematically illustrating a method of manufacturing a display device. FIGS. 6 to 9 schematically illustrate a cross-sectional view taken along line II-II′ of the plan view of the metal layer of the meta-layer of FIG. 4.

Referring to FIGS. 6 to 9, the manufacturing method of the display device 1 (see FIG. 1) may include disposing, on the substrate 100, a light-emitting element DPE including a subpixel electrode (211, see FIG. 3), an emission layer (212b, see FIG. 3), and an opposite electrode (213, see FIG. 3), disposing the capping layer 215 on the light-emitting element DPE, and forming, on the capping layer 215, the meta-layer 300 including the patterned metal layer 301 and the metal oxide layer 302.

Referring to FIG. 6, a subpixel circuit layer PCL including the subpixel circuit PC illustrated in FIG. 3 may be disposed on the substrate 100. The light-emitting element DPE including an organic light-emitting diode (OLED, see FIG. 3) including a subpixel electrode (211, see FIG. 3), an emission layer (212b, see FIG. 3), and an opposite electrode (213, see FIG. 3) may be disposed on the subpixel circuit layer PCL. The capping layer 215 may be disposed on the light-emitting element DPE.

The meta-layer-forming material 300a may be disposed on the capping layer 215. The meta-layer-forming material 300a may include aluminum (Al) or silicon (Si).

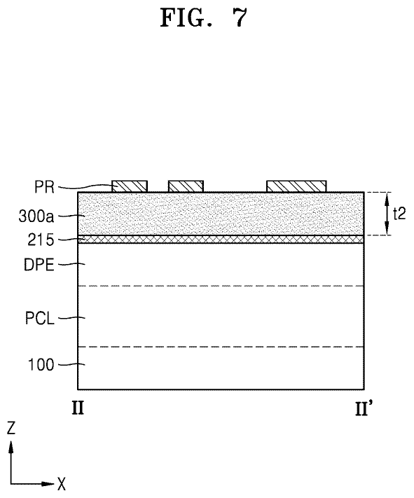

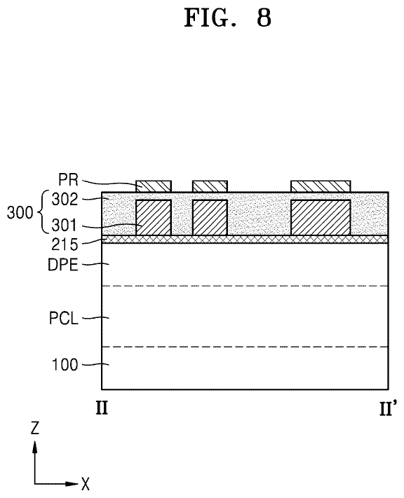

Referring to FIGS. 7 and 8, a photoresist PR may be disposed on at least a portion of the meta-layer-forming material 300a. At least a portion of the meta-layer-forming material 300a on which the photoresist PR is disposed may be oxidized to form the patterned metal layer 301 and the metal oxide layer 302. The degree to which the meta-layer-forming material 300a on which the photoresist PR is disposed is oxidized may be less than the degree to which the meta-layer-forming material 300a on which the photoresist PR is not disposed is oxidized.

Most of the meta-layer-forming material 300a on which the photoresist PR is not disposed may be oxidized to form the metal oxide layer 302. The meta-layer-forming material 300a on which the photoresist PR is not disposed may be oxidized even to a lower portion thereof adjacent to the upper surface of the capping layer 215 to form the metal oxide layer 302. On the other hand, only a portion adjacent to the photoresist PR, of the meta-layer-forming material 300a on which the photoresist PR is disposed, may be oxidized to form the metal oxide layer 302. In other words, a thickness of the metal oxide layer 302 disposed below the photoresist PR may be less than a thickness of the metal oxide layer 302 without the photoresist PR.

Instead of physically stacking the metal oxide layer 302 on the metal layer 301, the patterned metal layer 301, and the metal oxide layer 302 are formed by oxidizing at least a portion of the meta-layer-forming material 300a, and thus, the metal layer 301 and the metal oxide layer 302 may be chemically bonded to each other.

In case that the metal oxide layer 302 is formed by oxidizing the meta-layer-forming material 300a including aluminum (Al), the metal oxide layer 302 may include aluminum oxide (Al₂O₃). In another example, the metal oxide layer 302 may include silicon dioxide (SiO₂) in case that the metal oxide layer 302 is formed by oxidizing the meta-layer-forming material 300a including silicon (Si).

Aluminum (Al) may form plasmons in the entire range of visible light. In order to efficiently form the LSP at the interface 301s between the metal layer 301 and the metal oxide layer 302, the metal layer 301 may include aluminum (Al). However, the disclosure is not limited thereto. In another embodiment, the metal layer 301 of the meta-layer 300 may include silicon (Si). The metal oxide layer 302 may include silicon dioxide (SiO₂).

Since at least a portion of the meta-layer-forming material 300a is oxidized to form the metal oxide layer 302, the upper surface of the metal oxide layer 302 may be flat. The unoxidized meta-layer-forming material 300a may form the patterned metal layer 301. As illustrated in FIG. 4, the patterned metal layer 301 is provided in a rectangular shape and may reduce the reflectance of light incident from the outside of the display device 1 (see FIG. 1).

In the case of physically stacking the metal oxide layer 302 on the metal layer 301, a process of patterning the metal layer 301 may be necessary. The process of patterning the metal layer 301 may involve a complicated process as it requires an imprint process and an etching process, and the time required for the manufacturing process of the display device may increase.

In an embodiment, in case of disposing the meta-layer-forming material 300a and forming the metal oxide layer 302 by oxidizing at least a portion of the meta-layer-forming material 300a, a process of patterning the metal layer 301 and a process of physically stacking the metal oxide layer 302 are not required, and thus, the efficiency of the manufacturing process of the display device 1 may be improved, and the time required for the manufacturing process may be shortened.

A thickness t2 (see FIG. 7) of the meta-layer-forming material 300a, the meta-layer 300 including the metal layer 301 and the metal oxide layer 302, may be about 5 nm to about 10 nm. In case that the thickness t2 of the meta-layer-forming material 300a is less than about 5 nm, the thickness may not be sufficient to generate the LSP at the interface 301s between the metal layer 301 and the metal oxide layer 302. If the thickness t2 of the meta-layer-forming material 300a exceeds about 10 nm, light emitted from a light-emitting element may not be transmitted to the outside, and light extraction efficiency may be reduced.

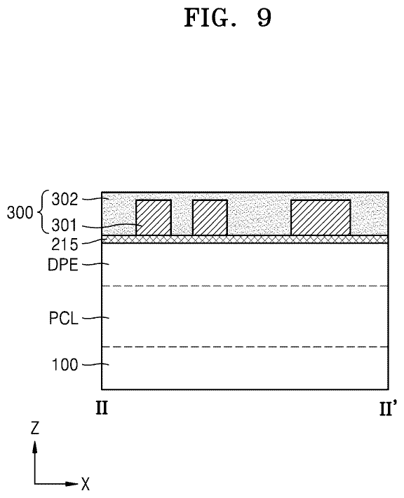

Referring to FIG. 9, the photoresist PR disposed on the metal layer 301 and the metal oxide layer 302 may be removed.

In an embodiment, the meta-layer 300 including the metal layer 301 and the metal oxide layer 302 may be provided on the capping layer 215, adjacent to the capping layer 215, to form the LSP and the electromagnetic field at the interface between the metal layer 301 and the metal oxide layer 302 to discharge photons trapped in the interface 213s1 between the opposite electrode 213 and the capping layer 215 or in the interface 213s2 between the opposite electrode 213 and the second functional layer 212c and improve the light extraction efficiency of the display device 1.

As the patterned metal layer 301 and the metal oxide layer 302 are formed by oxidizing at least a portion of the meta-layer-forming material 300a, a process of patterning the metal layer 301 or a process of physically stacking the metal oxide layer 302 may not be required, and thus the efficiency of the manufacturing process of the display device 1 may be improved and the time required for the manufacturing process may be reduced.

In concluding the detailed description, those skilled in the art will appreciate that many variations and modifications may be made to the preferred embodiments without substantially departing from the principles and spirit and scope of the disclosure. Therefore, the disclosed preferred embodiments of the disclosure are used in a generic and descriptive sense only and not for purposes of limitation.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate;
a light-emitting element disposed on the substrate and comprising a subpixel electrode, an emission layer, and an opposite electrode;
a capping layer disposed on the light-emitting element; and
a meta-layer disposed on the capping layer and comprising a patterned metal layer and a metal oxide layer.

2. The display device of claim 1, wherein, when viewed in a direction perpendicular to the substrate, the metal layer is patterned into a shape of a plurality of rectangles.

3. The display device of claim 1, wherein the metal layer and the metal oxide layer comprise a same metal.

4. The display device of claim 1, wherein the metal layer comprises aluminum (Al), and the metal oxide layer comprises aluminum oxide (Al₂O₃).

5. The display device of claim 1, wherein
the metal layer comprises at least one selected from silver (Ag), gold (Au), molybdenum (Mo), or vanadium (V), and
the metal oxide layer comprises at least one selected from silver oxide (Ag₂O), gold oxide (Au₂O₃), molybdenum oxide (MoOₓ), or vanadium oxide (V₂O₅).

6. The display device of claim 1, wherein the meta-layer has a thickness of about 5 nm to about 10 nm.

7. The display device of claim 1, wherein the metal layer comprises silicon (Si), and the metal oxide layer comprises silicon dioxide (SiO₂).

8. The display device of claim 1, wherein interfacial adhesion between the metal layer and the metal oxide layer is 5B as a result of a cross-cut test.

9. The display device of claim 1, wherein the metal oxide layer has a flat upper surface.

10. A method of manufacturing a display device, the method comprising:
disposing a light-emitting element comprising a subpixel electrode, an emission layer, and an opposite electrode on a substrate, the light-emitting element;
disposing a capping layer on the light-emitting element; and
forming, on the capping layer, a meta-layer including a patterned metal layer and a metal oxide layer.

11. The method of claim 10, wherein, when viewed in a direction perpendicular to the substrate, the metal layer is patterned into a shape of a plurality of rectangles.

12. The method of claim 10, wherein the forming of the meta-layer comprises:
disposing a meta-layer-forming material on the capping layer;
disposing a photoresist on at least a portion of the meta-layer-forming material; and
oxidizing at least a portion of the meta-layer-forming material to form the patterned metal layer and the metal oxide layer.

13. The method of claim 12, wherein the meta-layer-forming material on which the photoresist is not disposed is oxidized to form the metal oxide layer.

14. The method of claim 13, wherein only a portion adjacent to the photoresist, of the meta-layer-forming material on which the photoresist is disposed, is oxidized to form the metal oxide layer.

15. The method of claim 14, wherein a degree to which the meta-layer-forming material on which the photoresist is disposed is oxidized is less than a degree to which the meta-layer-forming material on which the photoresist is not disposed is oxidized.

16. The method of claim 14, wherein a thickness of the metal oxide layer disposed below the photoresist is less than a thickness of the metal oxide layer on which the photoresist is not disposed.

17. The method of claim 12, wherein the meta-layer-forming material and the metal layer comprise at least one selected from aluminum (Al), silver (Ag), gold (Au), molybdenum (Mo), or vanadium (V).

18. The method of claim 10, wherein the metal oxide layer comprises at least one selected from aluminum oxide (Al₂O₃), silver oxide (Ag₂O), gold oxide (Au₂O₃), molybdenum oxide (MoOₓ), or vanadium oxide (V₂O₅).

19. The method of claim 10, wherein interfacial adhesion between the metal layer and the metal oxide layer is 5B as a result of a cross-cut test.

20. The method of claim 12, wherein the meta-layer-forming material has a thickness of about 5 nm to about 10 nm.

21. The method of claim 10, wherein the metal layer comprises silicon (Si), and the metal oxide layer comprises silicon dioxide (SiO₂).
